(19) United States
(12) Patent Application Publication
(10) Pub. No.: US 2025/0068782 A1
(43) Pub. Date: Feb. 27, 2025

(54) ADAPTIVE MITIGATION OF FREQUENCY CROWDING OF SUPERCONDUCTING QUBITS VIA LASER ANNEALING

(71) Applicant: International Business Machines Corporation, Armonk, NY (US)

(72) Inventors: Eric Zhang, Sleepy Hollow, NY (US); Jason S. Orcutt, Katonah, NY (US); Jared Barney Hertzberg, YORKTOWN HEIGHTS, NY (US); Malcolm Scott Carroll, Cranbury, NJ (US); Takashi Ido, Tokyo (JP); NAOKI KANAZAWA, Kanagawa (JP)

(21) Appl. No.: 18/236,147

(22) Filed: Aug. 21, 2023

(51) Int. Cl. G06F 30/12; G06F 30/20; G06N 10/80

(52) U.S. Cl. CPC G06F 30/12; G06F 30/20; G06N 10/80

(57) ABSTRACT

Generate an initial tuning plan for a quantum computing device based on an initial screening; determine whether yield rate according to the initial tuning plan is acceptable, based on real-time analytics; facilitate carrying out tuning based on the initial tuning plan based on the determining indicating that the yield rate according to the tuning plan is acceptable; and repeat the determining and facilitating carrying out tuning steps based on tuning being incomplete and the yield rate according to the initial tuning plan being acceptable.

### BACKGROUND

The present invention relates to the electrical, electronic and computer arts, and more specifically, to computer-aided design of quantum computing systems.

A quantum computer exploits quantum mechanics; i.e., the fact that, at small scales, matter exhibits both particles and wave properties. Quantum computers use qubits, analogous to the bit in conventional digital computing.

Qubits can be realized using many modalities. Some common modalities include superconducting qubits based on circuit quantum electrodynamics (cQED) architectures, trapped ion qubits, spin-based qubits, neutral atoms, or photonic qubits. A common modality is superconducting qubits. Superconducting qubit modalities require cooling to cryogenic temperatures, using a cryostat, a dilution refrigerator, or the like. One pertinent example of a superconducting qubit is the fixed-frequency transmon. Quantum computers operate via quantum logic gates between qubits. Such gates may employ, for example, a microwave-activated coupling, a fast tunable coupling, or a parametric coupling between the qubits that form the gate.

A significant challenge for scaling fixed-frequency architectures is mitigating errors arising from lattice frequency collisions. The LASIQ (Laser Annealing of Stochastically Impaired Qubits) technique has been developed to increase collision-free yield of transmon lattices by selectively trimming (i.e., tuning) individual qubit frequencies via laser thermal annealing. Qubits can be addressed by using unique frequencies; however, undesirable collisions may occur, for example, when the frequencies of two nearest neighbor or next-nearest neighbor qubits become too close, or for example, when the frequency spacing between neighboring qubits are within a similar range as the qubit anharmonicity. Other variations of such frequency collisions may occur, and their precise definition will depend on the type of gates used in the quantum processor. Generally, care should be taken in the assignment of such qubit frequencies to ensure avoidance of frequency collision regions.

### SUMMARY

Principles of the invention provide techniques for adaptive mitigation of frequency crowding of superconducting qubits via laser annealing. In one aspect, an exemplary method includes the steps of generating an initial tuning plan for a quantum computing device based on an initial screening; determining whether yield rate according to the initial tuning plan is acceptable, based on real-time analytics; facilitating carrying out tuning based on the initial tuning plan based on the determining indicating that the yield rate according to the tuning plan is acceptable; and repeating the determining and facilitating carrying out tuning steps based on tuning being incomplete and the yield rate according to the initial tuning plan being acceptable.

Optionally, the method further includes, responsive to a subsequent determination that the yield rate according to the tuning plan is no longer acceptable, generating a new tuning plan, and repeating, for the new tuning plan, the determining and facilitating carrying out tuning steps based on tuning being incomplete and the yield rate according to the new tuning plan being acceptable.

In another aspect, an exemplary computer program product includes a computer readable storage medium having program instructions embodied therewith. The program instructions are executable by a processor to cause the processor to perform a method including: generating an initial tuning plan for a quantum computing device based on an initial screening; determining whether yield rate according to the initial tuning plan is acceptable, based on real-time analytics; facilitating carrying out tuning based on the initial tuning plan based on the determining indicating that the yield rate according to the tuning plan is acceptable; and repeating the determining and facilitating carrying out tuning steps based on tuning being incomplete and the yield rate according to the initial tuning plan being acceptable.

In still another aspect, an exemplary apparatus includes: a memory; and at least one processor, coupled to the memory, and operative to: generate an initial tuning plan for a quantum computing device based on an initial screening; determine whether yield rate according to the initial tuning plan is acceptable, based on real-time analytics; facilitate carrying out tuning based on the initial tuning plan based on the determining indicating that the yield rate according to the tuning plan is acceptable; and repeat the determining and facilitating carrying out tuning steps based on tuning being incomplete and the yield rate according to the initial tuning plan being acceptable.

Optionally, the at least one processor is further operative to, responsive to a subsequent determination that the yield rate according to the tuning plan is no longer acceptable, generate a new tuning plan, and repeat, for the new tuning plan, the determining and facilitating carrying out tuning steps based on tuning being incomplete and the yield rate according to the new tuning plan being acceptable.

As used herein, “facilitating” an action includes performing the action, making the action easier, helping to carry the action out, or causing the action to be performed. Thus, by way of example and not limitation, instructions executing on one processor might facilitate an action carried out by instructions executing on a LASIQ tool or a remote processor controlling a LASIQ tool, by sending appropriate data or commands to cause or aid the action to be performed. For the avoidance of doubt, where an actor facilitates an action by other than performing the action, the action is nevertheless performed by some entity or combination of entities.

One or more embodiments of the invention or elements thereof can be implemented in the form of a computer program product including a computer readable storage medium with computer usable program code for performing the method steps indicated. Furthermore, one or more embodiments of the invention or elements thereof can be implemented in the form of a system (or apparatus) including a memory, and at least one processor that is coupled to the memory and operative to perform exemplary method steps. Yet further, in another aspect, one or more embodiments of the invention or elements thereof can be implemented in the form of means for carrying out one or more of the method steps described herein; the means can include (i) hardware module(s), (ii) software module(s) stored in a computer readable storage medium (or multiple such media) and implemented on a hardware processor, or (iii) a combination of (i) and (ii); any of (i)-(iii) implement the specific techniques set forth herein.

Techniques as disclosed herein can provide substantial beneficial technical effects. Some embodiments may not have these potential advantages and these potential advantages are not necessarily required of all embodiments. By way of example only and without limitation, one or more embodiments may provide one or more of:
improves the technological process of computer-aided design of quantum computing systems, by improving tuning precision and/or tuning accuracy;
improves the technological process of computer-aided design of quantum computing systems, enhancing tuning yield as compared to prior art systems;
improves the performance of quantum computing systems designed in accordance with exemplary embodiments, by improving tuning precision as compared to prior art systems;
significant increase in yield of usable processors and/or modular processors. As used herein, “yield” refers to the fraction of quantum processors, of chips within a modular processor, or of qubits within the chip whose frequencies can be set so as to eliminate frequency collisions and/or to minimize gate error. The yield metric may account for frequency shifts or other random changes expected to occur subsequent to the tuning action. These may be assessed statistically using Monte Carlo models or other known methods of probability or statistical modeling. Usability in the context of quantum processors may be understood to mean benefits in terms of gate speed, gate fidelity, low collision count, or any other metric by which the quality of quantum computation may be improved;

Fewer collisions can lead to a reduced time to run a quantum algorithm and the supporting CPU (classical compute and corresponding energy for the calculation); i.e., savings of CPU time for the computer that runs the design algorithms.

These and other features and advantages of the present invention will become apparent from the following detailed description of illustrative embodiments thereof, which is to be read in connection with the accompanying drawings.

### BRIEF DESCRIPTION OF THE DRAWINGS

FIG. 1 shows an exemplary technique to check tuning progress, in accordance with an aspect of the invention;

FIG. 2 shows an exemplary technique with feedback during tuning, in accordance with an aspect of the invention;

FIG. 3 shows an exemplary technique with tuning constraints derived from a database module, in accordance with an aspect of the invention;

FIGS. 4, 5A, and 5B show aspects of calibration, in accordance with an aspect of the invention;

FIG. 6 shows an exemplary technique for tuning qubits to completion, and regenerating tuning plans based on tunable range on each single qubit, in accordance with an aspect of the invention;

FIGS. 7A, 7B, and 7C show aspects of a lattice and multi-pass tuning plans, in accordance with aspects of the invention;

FIGS. 8A and 8B show multi-pass tuning progression, in accordance with aspects of the invention;

FIG. 9 shows two tuning rounds and tuning precision for two-pass tuning, in accordance with aspects of the invention;

FIG. 10 shows an exemplary detailed method by which yield can be assessed, in accordance with aspects of the invention;

FIG. 11 shows a system block diagram, in accordance with aspects of the invention;

FIG. 12 depicts a computing environment according to an embodiment of the present invention; and

FIG. 13 shows the lattice of FIGS. 7A-7C with nodes regularly spaced, in accordance with aspects of the invention.

### DETAILED DESCRIPTION

LASIQ tuning is a process of progressive alteration of the resistances of Josephson junctions. To this end, any quantum element including one or more Josephson junctions may be tuned using LASIQ. For example, a fixed-frequency transmon qubit includes a Josephson junction shunted by a capacitor, whereby the Josephson junction behaves as a nonlinear inductor element that allows the qubit to exhibit non-uniform energy spacing between successive energy levels (i.e., the qubit exhibits anharmonicity which allows uniquely addressable ground and first excited states). By performing LASIQ on these fixed-frequency transmon qubits, the Josephson junction resistances, and correspondingly the transmon qubit frequencies, may be modified post-fabrication. In this context, LASIQ may therefore be used as a post-fabrication frequency trimming tool to engineer qubit frequencies to desired frequency patterns.

Lattices of fixed-frequency transmon qubits are typically fabricated in a specific lattice geometry (for example, a heavy-hexagonal lattice, square lattice, or the like). Furthermore, qubits are known to suffer from frequency crowding, which arises from energy level degeneracies between neighboring and next-nearest-neighboring qubits, and even higher order connectivity may be considered. This frequency crowding may be quantified by the number of collisions that the multi-qubit lattice exhibits. Each collision type may be defined by frequency bounds within which qubit pairs, or triplets are forbidden to enter. If these bounds are trespassed, high gate errors, and therefore low gate fidelities will be observed. LASIQ is a laser-annealing methodology that may be used to iteratively tune the Josephson junction resistances using a sequence of annealing ‘pulses,’ to gradually and monotonically approach their respective target resistance, thereby engineering the qubit frequencies into desired values, levels, patterns, or the like.

The term ‘pulse’ as used herein denotes a laser anneal operation that is performed by applying laser power to a target element (e.g., Josephson junction) for a specified duration (anneal time) to tune the target element. In the context of exemplary embodiments of the disclosure as discussed herein, laser tuning methods are provided to tune junction resistances of Josephson junctions in a progressive and incremental manner wherein multiple ‘pulses’ are applied to a given Josephson junction to tune the junction resistance of the Josephson junction to a target junction resistance, which is to be contrasted with conventional approaches that tune a Josephson junction to a target junction resistance using only one laser pulse.

The term “iterate” or “iteratively” used herein and in the context of a laser annealing process is meant to refer to the process which comprises a single laser pulse along with associated control, measurement and computation by the LASIQ computer system and apparatus to determine the necessary anneal time and power for the anneal pulse. A laser annealing iteration, or LASIQ iteration, therefore, refers to the entire process by which a Josephson junction is measured, the anneal power and time is determined, and the anneal pulse is performed. In this sense, one iteration involves the entire sequence of the laser annealing system and apparatus as it pertains to one step of the progressive approach to the resistance target for one Josephson junction. The tuning of one junction to completion (i.e., reaching its resistance target) may therefore be said to progress “iteratively.” The term “iterative process” as used herein, is meant to generally refer to a set of iterations, as applicable to one or more qubit devices, or the like, including Josephson junctions, whereby the one or more qubit devices are tuned with the purpose of approaching their respective targets.

The term ‘round-robin’ or ‘annealing round’ as used herein and in the context of a laser annealing process, is meant to refer to a tuning process in which all qubits on a multi-qubit device undergo the laser annealing process in succession, and which may be followed by another round-robin or multiple round-robins in succession. Such round-robins may be continuously performed until all qubits on the multi-qubit device reach their respective targets. For example, a singulated quantum chip may include a number of qubit devices (e.g., 100 qubits, denoted Q1, Q2, Q3, . . . , Q100) including Josephson junctions. In an exemplary embodiment of a tuning method, Q1 will first be tuned with one or more annealing iterations, as desired. The process will proceed to Q2, where one or more annealing iterations may be performed, as desired. The process will then proceed to Q3, etc. until finally Q100 is tuned with one or more annealing iterations, as desired. This entire process from Q1 to Q100 is defined as one round-robin. After this first round-robin, the process may return to Q1, and will repeat again until Q100 is reached. The process of successive round-robins may provide time control and delay between iterations or sets of iterations, such that the Josephson junctions may be permitted to relax to their final resistances prior to the next annealing iteration or set of iterations.

During LASIQ tuning, the frequencies typically monotonically and iteratively approach the target, based on successive laser ‘pulses’ that asymptotically move the qubit frequencies to a target frequency. The asymptotic and gradual tuning approach reduces the risk of overshooting or undershooting the junction resistances. To ensure this progressive approach to target, various calibration structures may be utilized towards determining the typical tuning rate and tuning range of the Josephson junctions, using dedicated test structures that may be interleaved and/or situated on unused locations of the chip (for example, the ‘kerf of a chip, which is an unused location that physically separates two adjacent dies on a wafer, or coupon), or using a ‘sister’ chip, which has undergone the same process steps during fabrication. However, despite the care taken to avoid overshooting or undershooting, the statistical likelihood of such anomalies increases and is practically unavoidable as quantum chips scale to the hundreds, or thousands of qubit scales and greater. In other words, given the large scales of modern quantum processors, it is essentially impossible for all qubits to successfully achieve their target frequencies as designed in an initial tuning plan. This is detrimental to chip yield (for example, as assessed by the collision-free probability), which results in the chip being discarded (e.g., due to the anticipated high gate-error rates). The net effect involves significant reduction in the resulting number of usable processors, given a batch of chips that are to be tuned. One or more embodiments provide techniques for in-situ and adaptive target modification to be able to correct for these tuning errors and imperfections to increase the yield of quantum processors.

Yield metrics of quantum processor(s) may be assessed through both deterministic and statistical analysis, or the like. For example, one yield metric commonly used may include the number of collisions in an as-tuned chip, or a comparison of collision numbers before and after LASIQ tuning. However, more sophisticated methods may be implemented to determine the expected number of collisions that may be obtained after completion and cooling of a quantum processor in a cryostat. Such methods apply to single-chip processors and both within and across each chip of a modular device. This may be accomplished, for example, using a Monte Carlo method, or the like, by which the predicted frequencies undergo a random scatter with a magnitude defined by a frequency precision interval (e.g., 20 MHZ), and the impact of the scatter of the expected number of collisions is quantitatively assessed. Equivalently, it is possible to calculate the expected probability of a zero-collision chip on a non-modular or modular device. Another metric that may be used is predictions of gate error rates, gate fidelity, and/or gate speed. Such models may take into account, for example, qubit coherence times in addition to qubit frequencies after LASIQ tuning. Such models are architecture dependent. However, one or more embodiments for adaptive and in-situ modifications of such tuning plans are not limited to any specific architecture, but rather, given a known architecture of lattices and qubit coupling mechanisms and acceptable yield metrics, one or more embodiments may be implemented to generally and significantly improve the fraction of acceptable chips.

As noted above, the LASIQ (Laser Annealing of Stochastically Impaired Qubits) technique has been developed to increase collision-free yield of transmon lattices by selectively trimming (i.e., tuning) individual qubit frequencies via laser thermal annealing. LASIQ tuning can be used in one or more exemplary embodiments. However, it is to be understood that embodiments described herein requiring frequency tuning (e.g., of functional qubits, quantum logic structures, quantum coupling structures, or any general elements that include one or more Josephson junctions) are not limited solely to the use of LASIQ tuning, but rather, any frequency tuning capability of qubits and/or elements based on Josephson junctions may be utilized to satisfy the frequency tuning requirements needed to successfully implement a quantum device including one or more interconnected processors, as may occur in a modular device (i.e., various embodiments are applicable to both modular and non-modular systems). In one exemplary embodiment, a LASIQ tool is used to perform laser-annealing of Josephson junctions of fixed-frequency transmon qubits, which are connected in a heavy-hexagonal lattice, whereby nearest and next-nearest neighboring collisions are considered.

Tunable superconducting qubit architectures can be employed in some instances. In one or more embodiments, significant gain in yield may be obtained using techniques to selectively trim frequencies of individual qubits and various elements based on Josephson junctions, that may be part of tunable superconducting qubit architectures.

One or more embodiments, during the tuning process, assess the collisions and yield in real-time, using known metrics as described elsewhere herein, to see the extent to which tuning imperfections impact success metrics. Such success metrics include total collision counts, collision-free probability, gate-error rates, gate speeds, and the like, which may be assessed using deterministic and/or statistical methods. If the (negative) impact is beyond the acceptance criteria for the chip(s) under consideration, a new tuning plan is generated based upon the existing constraints of tunability, and tuning proceeds according to this new plan.

Tunability may be assessed, for example, using the calibration methodology described elsewhere herein, by which a set of trial junctions are laser-annealed to determine the tuning rate and tuning range, and any other functional parameter deemed necessary to tune junctions to completion. In particular, in one or more embodiments, tuning rates are used to estimate the laser annealing duration required to substantially tune a junction to completion, and the tuning range (i.e., maximum tuning limit) is used to constrain the generation of the tuning plan for qubit frequencies (as used herein, “substantially tune” means the tuning needed to tune a junction to a target completion band, which could be, in a non-limiting example as discussed elsewhere herein, 0.3% of the target resistance. The 0.3% figure is exemplary and can be modified as needed by the skilled person based on heuristics depending on the domain of interest and application). As an example, a tuning plan may include a fixed multitude of frequency levels, and each qubit should reside on one of these levels, and also be tunable to these levels. The latter condition is determined by calibration of similar junctions, whereby these similar junctions are tuned to observe how far their resistances may be shifted. By appropriate assignment of each qubit to a frequency level, and within tunability constraints, it is possible to avoid level degeneracies that may cause unwanted crosstalk (i.e., collisions) and therefore low gate fidelity. Other examples of methods by which a tuning plan is generated can include a fixed frequency plan, or an optimization protocol by which each qubit may reside within a range of frequencies, whereby this range (constrained by collision bounds) is subject to the frequency value of neighboring or next-nearest neighboring qubits. The mentioned exemplary methods for generating tuning plans are not intended to be exhaustive, but rather serve as illustrative examples of methods by which tuning plans can be generated given a lattice topology, as is the case in lattices of superconducting qubits. In general, any other tuning plan generators which adequately mitigate frequency collisions would be considered acceptable, as will be apparent to the skilled artisan given the teachings herein. Such tuning plans outside the scope of fixed-frequency patterns and optimization protocols are referred to herein as “ad-hoc” plans.

Frequency collision analysis and collision-free yield may be an important metric to consider when determining the yield of a tuned chip. Collision bounds for a given quantum processor architecture may be derived using known empirical and/or first-principles gate error models for the superconducting qubit architecture being tuned. As an illustrative embodiment, a fixed-frequency transmon qubit pair can be modeled as undergoing ZX interaction which is used to realize a CNOT (controlled NOT) gate. High-fidelity gates typically require this interaction to be controlled by assigning appropriate bounds to the relative frequency difference between nearest- and next-nearest neighboring transmon qubits pairs. Gate error modeling should therefore account for this interaction while accounting for various sources of noise; for example, that arising from static ZZ interactions among qubits. In one or more exemplary methods, the gate error modeling, and therefore frequency collision bounds, may be performed by empirically measuring the frequencies of devices and the corresponding gate fidelities that may be achieved on the given architecture.

The skilled artisan, given the teachings herein, can adapt known tuning plan generators to implement one or more embodiments. Nominally, junction resistances increase, and therefore qubit frequencies decrease upon tuning. Therefore, for example, if a qubit or group of qubits undershot in resistance (i.e. reached their tuning limits before they could reach target), one or more embodiments generate a new tuning plan subject to the constraint that the undershot qubits should not be moved any more, since there is no more tuning range left in those qubits. On the other hand, if, for example, a qubit or group of qubits overshot, one or more embodiments generate a plan that allows them to continue tuning if they have not yet reached their estimated maximum range. In some embodiments, qubits tune bi-directionally. In this aspect, they can be tuned both up and down as needed, within the tuning range limits. The nature and directionality of tuning may be determined based on the calibration trial junctions, which will be subjected to laser annealing at various combination of laser power and time.

Thus, one or more embodiments implement a new tuning plan on top of the existing plan, subject to the constraint of how far previous qubits have already been tuned. For example, if the expected tuning range is 10% and the qubit has already gone 9%, only allow 1% additional tuning. In one or more embodiments, the constraints include history per qubit and the desired target and constraints are adaptively changed on the fly and new optimized tuning plans are generated. One or more embodiments constrain the tuning process so that the tuning process never continually does worse. One or more embodiments employ significant computing power for the repetitive optimizations.

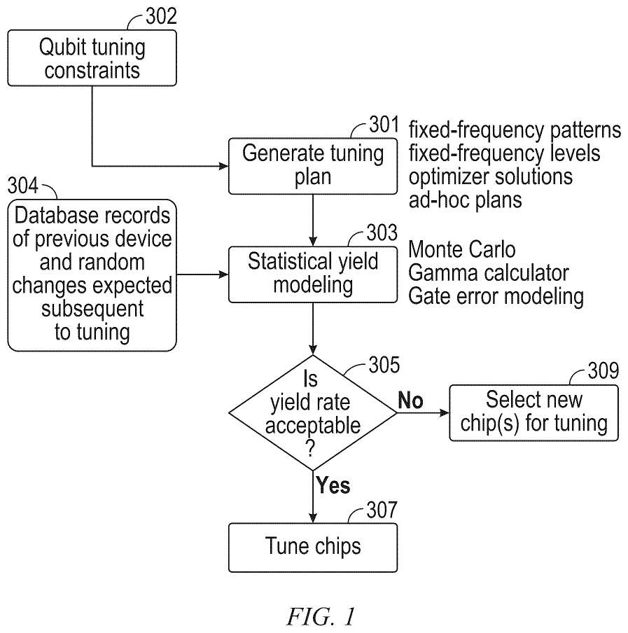

Referring to FIG. 1, one or more embodiments provide a simple linear scheme to assess whether a selected chip or set of chips is suitable for tuning (for example, for a single device, or a plurality of devices that will be part of the same modular device). This process is termed ‘screening’ and is used to ensure that all chip candidates allocated for tuning are of sufficient predicted post-tuning quality that they should be entered into the LASIQ tuning queue. This linear screening scheme is used both on new untuned chips, or chips that have been partially tuned and had their plans regenerated based on their existing constraints, as described elsewhere herein. The yield is calculated using metrics described elsewhere herein, such as the number of collisions, collision-free probability, gate fidelity predictions, and the like. To perform this screening process, first, the qubit tuning constraints are identified in step 302. These constraints may be identified using the calibration protocol as discussed elsewhere herein, whereby the frequency tuning range is determined, and the collision bounds are defined. In the case of a new chip, the tuning range may be accomplished solely by accounting for the total tuning range; in the case of an already partially tuned chip that is undergoing a revised tuning plan, the calibration tuning range, as well as the already tuned range is taken into account as described elsewhere herein. Next, a tuning plan is generated in step 301. This may be achieved using any variety of tuning plan generators that may be used to satisfy frequency constraints and achieve target gate fidelity. Such tuning plans include fixed-frequency patterns, fixed-frequency levels, optimizer solutions involving significant computational requirements, ad-hoc plans, or the like. Exemplary plans are described elsewhere herein.

In addition, a variety of statistical yield models may be used in step 303 to assess the tuning plan; e.g., deterministic or statistical methodologies such as collision counting and Monte Carlo techniques, a Gamma calculator (i.e., the estimated overhead for probabilistic error cancellation as known from the IBM Research paper Ewout van den Berg et al., “Probabilistic error cancellation with sparse Pauli-Lindblad models on noisy quantum processors,” Nature Physics, 2023 May 8:1-6.), gate error modeling (e.g., using known empirical and/or first-principles gate error models for the superconducting qubit architecture being tuned), and the like. Generally, step 303 is representative of running collision analysis, yield, and/or predictive analytics to determine expected success rate. A pertinent input to the statistical analysis will be any random changes to be expected in qubit frequencies between the time of LASIQ tuning and the time of chip cooling and operation in a cryostat. These may be estimated from records of past devices as previously measured and stored in a database 304 accessed by the statistical yield modeling algorithm 303. Additionally, there is a material relaxation of the Josephson junction that occurs post-annealing, where junction resistances relax and stabilize to their final values, and this relaxation may be compensated and/or accommodated using an appropriate time delay between post-LASIQ and cryogenic frequency measurements. In decision block 305, the system checks whether this is satisfactory; i.e., whether the yield rate is within acceptance criteria. If so (YES branch), proceed to (e.g., LASIQ) tuning in step 307; else (NO branch), select a new chip or set of chips to be screened at 309. As will be discussed further below, the chip or plurality of chips under consideration in FIG. 1 may arise not only from an entirely new set of fabricated chips, but may arise from a chip or set of chips that have been poorly tuned and needing their tuning plans regenerated based on new parameters, and with a feedback loop implemented to ensure that the tuning plans at any given time are achievable and satisfy yield requirements. Therefore, it may be understood that the method shown in FIG. 1 may be applied before any tuning has begun or during the process of tuning (i.e., in-situ screening). One or more embodiments address techniques to deal with tuning that is progressing poorly and requires a re-screening process including the steps shown in FIG. 1. As also discussed below, if tuning is complete, post-tuning analysis can be carried out; if tuning is not complete, reassess yield/collision and if not acceptable regenerate the tuning plan. We have found that the regenerated tuning plan will often be quite different than the original. In this sense, each chip at any given time may be considered to be an entirely new chip, merely with different boundary conditions from its previous rounds of tuning.

FIG. 1 thus depicts a screening methodology. FIG. 1 shows how to generate a tuning plan and assess the yield of a set of chips; it can be used where screening (or re-screening) is called for in the subsequent figures. The criterion for acceptance at 305 of FIG. 1 helps determine whether the chip plus its tuning plan is satisfactory for tunability.

Further regarding tuning plan generators (optimizers) the IBM CPLEX optimizer (available from International Business Machines Corporation, Armonk, NY, USA) provides a software solution for linear programming optimization problems, which is broadly applicable to problems of the type described here (i.e., generating frequency tuning plans given frequency collision constraints). Other algorithms may, for example, attempt to optimize the utility of quantum processors by computing the longest possible collision-free chain, ring, or other such conformation given the constraints on tunability, collision bounds, and lattice geometry. Optimizers using randomized plan generators or ad-hoc generators can also be used, for example, in the case of Monte Carlo tuning plan generators whereby a large number of frequency patterns are attempted to sample the solution space. Other algorithms, such as algorithms for collision avoidance, may cycle through different topologies to incrementally shift qubit frequencies by parameterized amounts to find a collision-free (or collision-reduced) number of qubits in the chosen assessment topology until convergence or the greatest number of interconnected collision-free qubits within a computational time limit. Static optimizers using Monte Carlo tuning or simulated annealing might also be used.

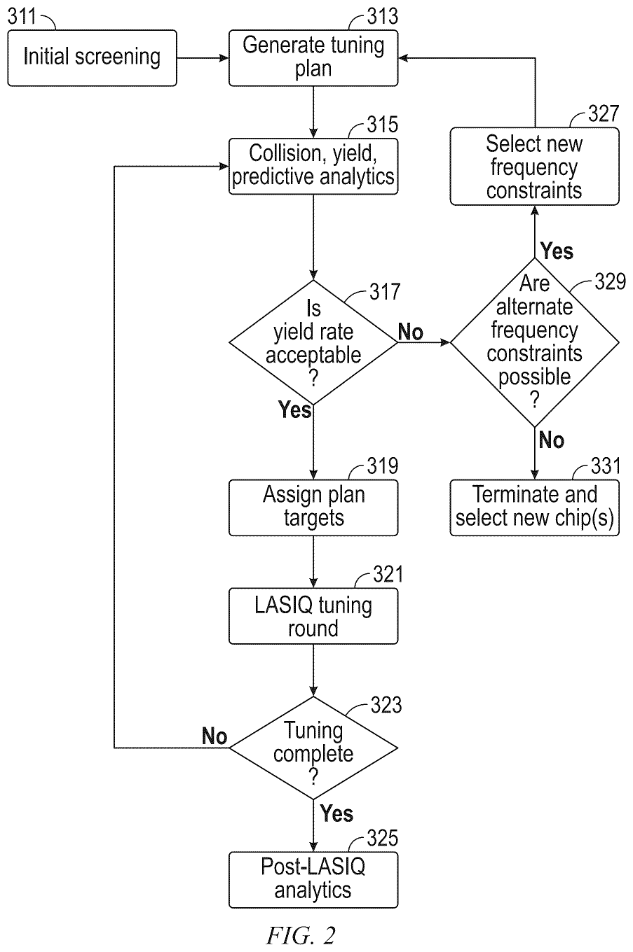

FIG. 2 shows an exemplary process of feedback for in-situ yield improvement by regenerating new tuning plans as the tuning progresses. Indeed, FIG. 2 shows aspects of feedback during tuning. In step 311, carry out initial screening. In step 313, generate a tuning plan. In step 315, perform predictive yield analysis (e.g., Monte Carlo analysis) and collision analysis in-situ during LASIQ tuning. In decision block 317, determine whether the yield rate is acceptable. If so (YES branch), assign the plan targets to the lattice in step 319, and then proceed to LASIQ tuning in step 321. On the other hand, if the yield rate is not acceptable (NO branch of decision block 317), proceed to decision block 329 and determine whether alternate frequency constraints are possible (as pertaining to the re-screening process beginning at block 302, FIG. 1-Block 329 in FIG. 2 ties into block 302 in FIG. 1—for example, frequency constraints could change because some qubits have overshot and it is appropriate to impose new frequency limits so rescreen by repeating all of FIG. 1, beginning at 302). If not (NO branch of block 329), terminate the process and select new chip(s) for screening at 331. If alternate frequency constraints are possible (YES branch), select the new frequency constraints in step 327 and return to step 313 to generate a new tuning plan. Predictive yield analytics 315 is performed, and if it is satisfactory in decision block 317, the new plan targets are assigned at 319. After the LASIQ tuning in step 321, determine in decision block 323 whether tuning is complete. If not (NO branch), logical flow proceeds back to step 315 to assess the quality of the tuning round. On the other hand, if tuning is complete (YES branch), proceed to post-LASIQ analytics in step 325.

Tuning success or completion of a junction may be determined by the proximity of a junction resistance to its target value. For example, a junction may be deemed ‘complete’ when the current junction resistance is measured to be within an acceptance threshold (e.g., 0.3%) of the target resistance. That is, if a target resistance is, for example, 10K Ohms, an acceptable success band may be defined to be +/−30 Ohms, or equivalently, a range from 9970 Ohms to 10030 Ohms. It is to be noted that the term ‘current junction resistance’ as used herein is meant to denote a junction resistance measured in the sense of occurring in or existing at a present time, or a most recently measured junction resistance.

A specific quantum computing-based device (e.g., a singulated die intended as a distinct quantum processor chip) may be deemed complete when all junctions are tuned satisfactorily (e.g., within 0.3%) of target resistances, and statistical yield models indicate that the expected likelihood of collisions or probability of zero-collision yield lies below an acceptance threshold. The overall quality of tuning, for example, may be assessed by observing a smooth and monotonic progression towards target resistances, starting from initial resistances. Note that it is also possible, for example, that upon a certain number of annealing rounds of LASIQ tuning for a given plan in FIG. 2, that the yield rate will never be acceptable for the given plan. In a typical case, a maximum of 10 annealing rounds (for example) are therefore allowed for a given plan, as it has been typically and empirically the case that a larger number of iterations would indicate an inability of the tuning to converge to the desired target frequency plans. If the qubits do not reach target within this number of annealing rounds, the plan is deemed to be unapproachable and a new tuning plan is generated. In this case, the flow may also progress to block 329, and a new plan is generated. The number of acceptable annealing rounds may also be determined heuristically, based on the rate of progression towards targets as may be determined from historical tuning progressions, and/or calibration tuning rates on trial junctions.

The frequency of feedback (i.e., determining in decision block 317 whether the yield rate is acceptable) can occur after measuring the resistances of all tunnel-junctions in the chip (a single round of measurement) and applying one tuning dose to those which have not achieved their targets. Or alternatively, feedback can be performed after every measurement occurrence on each junction (which is more computationally intensive). In other words, the feedback may occur after each round of annealing across the entire chip, or after each iteration of annealing on each individual junction. Note that the check in the alternate frequency constraints decision block 329 is defined by the existing tuning progression. For example, if a qubit undershot its target because it ran out of tuning range, then the new constraints should forbid further tuning on this undershot qubit since it cannot be tuned any further. As noted, in step 327, the undershot qubit will now have new and different constraints than that which it started with (namely, it will be limited to its current frequency as it can no longer be tuned further). In step 313, a tuning plan is then (re) generated based on these constraints.

In the present context, note that a “round-robin” refers to measuring and tuning all the junctions on a qubit chip in one round in succession and then repeatedly re-doing the round with the goal of getting all the qubits to reach their targets at roughly the same time. For example, a singulated quantum chip may comprise a number of qubit devices (e.g., 100 qubits, denoted Q1, Q2, Q3, . . . , Q100) comprising Josephson junctions. In an exemplary embodiment of a tuning method, Q1 will first be tuned with one annealing iteration, as desired, if Q1 is not at its respective target resistance. The process will proceed to Q2, where one annealing iterations may be performed, as desired, if Q2 is not at its respective target resistance. The process will then proceed to Q3, etc. until finally Q100 is tuned with one or more annealing iterations, as desired. This entire process from Q1 to Q100 is defined as one round-robin. After this first round-robin, the process may return to Q1, and will repeat again until Q100 is reached. The process of successive round-robins may provide a means of time control and delay between iterations or sets of iterations, such that the Josephson junctions may be permitted to relax to their final resistances prior to the next annealing iteration or set of iterations. In an alternative approach, just iterate on a single junction until it reaches its target, then move to the next one, until all qubits are complete. In this manner, the tuning principally occurs in a single round-robin. Subsequently, yield analytics 315 may be performed and either another annealing round-robin starts at 321, or a new tuning plan or chip is selected if yield proves unsatisfactory. Either approach of tuning (i.e., involving tuning all the junctions on a qubit chip in one round-robin in succession, or iterating on a single junction until it reaches target), can be used in connection with one or more embodiments.

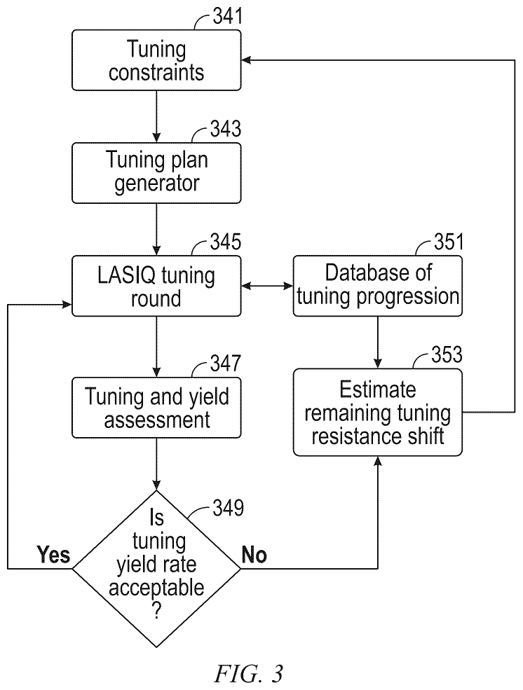

Referring now to FIG. 3, which shows how the historical resistance shift is accounted for in the annealing flow using a database system, which may include a local or cloud database server interfacing with the LASIQ system, and where all data with respect to the tuning progression and anneal parameters may be stored. Consider a case where there are tuning constraints 341; e.g., a tuning range, collision bounds, or the like. Based on the tuning constraints 341, generate a tuning plan with a tuning plan generator at 343 and then, at 345, tune in accordance with same. During the LASIQ tuning round at 345, the data acquired during each junction anneal is sent to a database system for future use. The data acquired during each junction anneal may include, but is not limited to: chip identification parameters (e.g., lot, wafer, processing date), time stamp, anneal power, anneal time, junction resistance, number of pulse iterations, and the like. Pertinently, using this database it is possible to reconstruct the entire tuning history of a series of junctions that have been subjected to the LASIQ process, and will be used to determine constraints on tunability in the event that tuning plans must be regenerated. In step 347, carry out statistical yield modelling. In decision block 349, determine whether the tuning yield rate is acceptable. The tuning yield considers both the tuning success (e.g., the total success rate of reaching junction target resistances), as well as associated analysis of collisions and the probability of collision-free yield, amongst other metrics. It is in step 347 where qubit undershoot and overshoot is considered, and an assessment is carried out as to whether the existing tuning plan (with the aforementioned tuning imperfections of overshoot/undershoot) is within the acceptance criteria. If so (YES branch), continue tuning (logical flow returns to step 345); otherwise (NO branch), estimate the remaining resistance shift required to reach the target at 353, based on database of historical tuning progression 351. For example, if a qubit overshoots in resistance, estimate the remaining tuning resistance shift that is available. If a qubit undershoots in resistance, constrain this qubit so no more tuning occurs. In some instances, both positive and negative tuning are permissible, in which case just adjust the metrics of overshoot and undershoot based on the direction chosen for each qubit, and based on calibration tuning range accordingly.

Still considering FIG. 3, in one or more embodiments, the historical anneal progressions of every single qubit/junction being tuned can be used to reconstruct history and impose new constraints based on the history, as needed.

It is worth noting that the terminology “tuning distance” can also be employed but the word “distance” may confuse the reader into thinking that a physical distance is intended; thus, terminology such as “distance to target” is rendered as “resistance shift required to reach target” or the like.

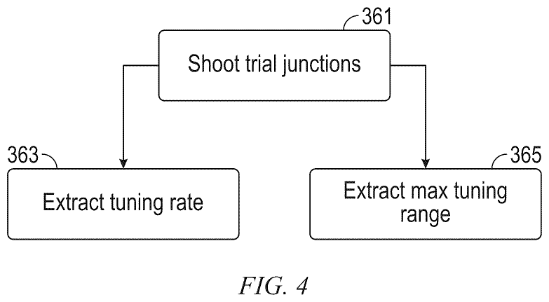

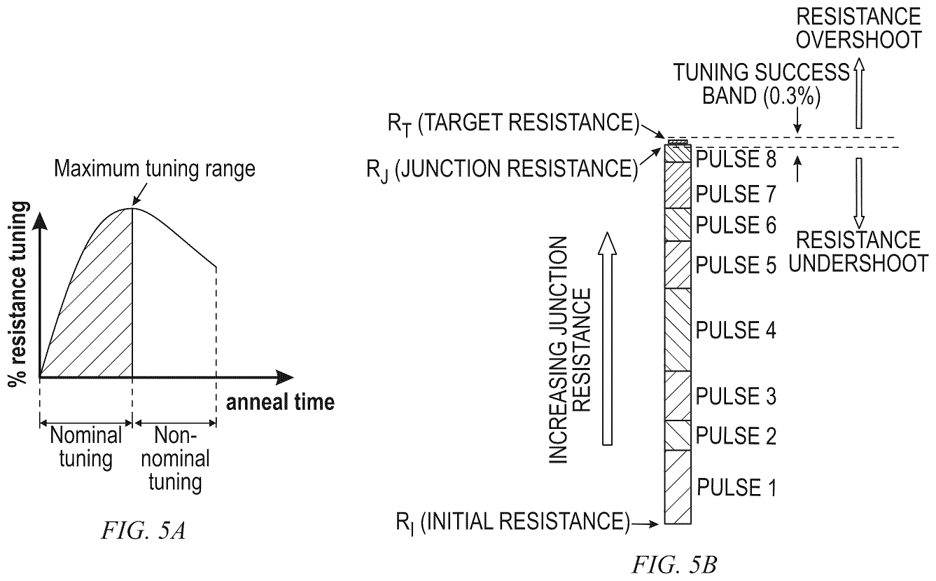

Referring now to FIGS. 4, 5A, and 5B, consider an exemplary calibration sequence to extract tuning parameters. This calibration sequence can be achieved, for example, on a set of trial junctions 361 closely related to the actual tuned junctions. Non-limiting examples of trial junctions include on a sister chip, or trial test junctions on the actual chip (for example, trial junctions may be placed on the kerf of a chip, which is a connective region between two adjacent dies on a wafer or coupon (i.e., set of non-singulated or undiced dies)). More specifically, the tuning rate may be used to estimate the annealing time and annealing power required for each junction for the actual chip being tuned, while the tuning range allows the frequencies achievable to be constrained in the tuning plan, to negate the possibility of generating a tuning plan that is impossible to obtain in practice. FIG. 5A schematically presents a typical tuning curve. Under normal circumstances (nominal tuning), the junction being annealed will gradually increase in resistance, until it reaches a peak, which may, for example, be near or around 15%. However, variations in junction process methodologies will typically impact the exact value of the maximum tuning range, and it is therefore appropriate to determine this empirically.

It may be assumed that junctions that have undergone the same process will have similar tuning ranges and tuning rates, which therefore enables the calibration methodology depicted in FIG. 4 to remain valid. In an exemplary embodiment, the tuning plan generated ensures all junctions reside within their nominal tuning regime, as determined by the calibration curve generated in FIG. 5A by annealing trial junctions, such that positive resistance changes occur. In other embodiments of tuning, a non-nominal tuning regime is used, which may occur after the monotonically increasing region is passed (either using excess anneal time or anneal power). In this non-nominal tuning regime, the junctions may exhibit negative relative resistance change, whereby the junction resistance begins to decrease with further tuning. In such cases, a relative negative tuning shift may be permitted in the frequency constraints (327, FIG. 2) and in the regeneration of tuning plans (313, FIG. 2). However, in other scenarios, it may be the case that the junction resistance simply plateaus and stabilizes, and no significant change in resistance subsequently occurs. This variability in the non-nominal regime is determined by material and fabrication details in the process by which the junctions are formed. Typically, the junction process is not controlled to the extent needed to repeatably reconstruct this non-nominal tuning regime. Given its uncertainty, it is therefore desirable to remain in the more predictable nominal tuning regime, wherein the junction resistances monotonically increase up to a maximum value. In an exemplary embodiment, to ensure that junctions remain within this nominal tuning regime, it is therefore typical that this maximum tuning limit be applied as a constraint for each qubit in a tuning plan generator. However, it is to be understood that the methods described herein are not exclusively limited to the nominal tuning regime; rather, if the non-nominal tuning regime may be appropriately and repeatably controlled, the methods described herein may be similarly applied to both positive and negative tuning rates and tuning limits. In one or more embodiments, estimate what this tuning curve looks like in order to accurately tune a junction, given knowledge of its initial resistance and target resistance. Two pertinent metrics as described elsewhere herein include the maximum tuning range (extracted at 365 in FIG. 4), which can be extracted based on the maximum achieved percent resistance tuning (vertical axis); and the tuning rate (extracted at 363 in FIG. 4), which is related to the slope of the tuning curve in the nominal tuning regime (positive % R tuning). For example, the maximum tuning range for a given laser power setting may be determined using an interpolation function (polynomial, logarithmic, or the like) where the maximum value may be extracted from the extrema of a curve resulting from a linear or nonlinear regression curve fitting process. In such a case, the tuning rate may be determined based on the slope of the interpolation function that is utilized.

In the curve of FIG. 5A, anneal time is plotted on the horizontal axis. In FIG. 5A, as the junctions are exposed to laser pulses, the x-axis can be thought of as a pulse of anneal time. For example, pick a laser power (say, 2 W) and anneal for a certain amount of time and a certain amount of resistance change will be obtained on the y-axis. Resistance increases until the maximum is reached. If exposure of the junction is continued, the junction resistance change enters the non-nominal tuning regime and begin to exhibit negative relative resistance change. For example, start at 10,000Ω. The maximum tuning range as determined by calibration data may be 15%, corresponding to 1,500Ω. Tune for a while and get to around 11,500Ω. After at least one additional tuning ‘pulses’ (i.e., annealing iterations), the resistance goes backwards; that is called reverse shift. The reverse shift region is hard to predict. Sometimes resistance plateaus but does not reverse. Sometimes resistance increases slowly; there are a variety of possible tail behaviors that are hard to predict/engineer. However, the nominal tuning range is generally predictable. It is often desirable to remain in the nominal tuning regime; however, in general, where adequate data on predictability is available, the reverse shift can be employed for tuning purposes. The maximum tuning range can be, for example, about 15%, depending on factors such as the details of the fabrication process and the environment. If starting, for example, with 10,000Ω, the maximum permissible tuning change for this junction in generating tuning plans would be about 1500Ω.

Calibration results are based on using statistical methods to fit this tuning calibration data to tuning curves, to obtain the aforementioned tuning rate and tuning range. FIG. 5B depicts a typical anneal progression that makes use of the calibration curves, to gradually and monotonically tune a junction to target, starting from initial resistance to a final target resistance. The junction undergoes 8 total anneal ‘pulses’ which include successive anneal sequences of varying times that have been selected to gradually approach the resistance target. A band of success is defined, (e.g., within 0.3% of the target resistance), whereby the tuning will stop when the junction resistance reaches this target band, and the tuning for this junction is subsequently deemed successful. The target success band in resistance corresponds to a target success band in qubit frequency, and is selected based on the level of tuning precision and tolerance that may be acceptable in terms of impacting the final acceptable yield. In the case where the final pulse surpasses the upper bound of the resistance success band, the junction is deemed ‘overshot,’ and if the junction plateaus or undergoes reverse shifting (i.e., passes its nominal tuning regime and enters the non-nominal tuning regime, as depicted in FIG. 5A), the junction is deemed ‘undershot.’ It is with reference to FIG. 5B, for example, that measures of tuning ‘success,’ ‘overshoot,’ and ‘undershoot’ can be defined.

At the bottom of FIG. 5B, consider, for example, an initial resistance—e.g., 10,000Ω. In the example, there are eight pulses. Note at top the target resistance RT. It is desired to (gradually) change a certain junction resistance from the initial resistance R_{I} to a designated target R_{T}, using some plurality of pulses. The number of pulses in the beginning of the iterative tuning process is not known a priori. Define an exemplary target success band of 0.3%. The tuning progresses by a series of laser pulses, or annealing iterations, labeled ‘PULSE 1,’ ‘PULSE 2,’ . . . , ‘PULSE 8.’ Here, on the eighth pulse, enter the target band (success). If the resistance went beyond the target success band, that would be overshoot and the resistance would typically be left there, as a tuning failure (unless taking advantage of reverse shift). The resistance could also undershoot, where it has plateaued and is not getting any closer to the goal; this is also a tuning failure. In either case, the estimated yield is determined and if unsatisfactory, a new tuning plan is generated based on the constraints of overshooting or undershooting a particular qubit.

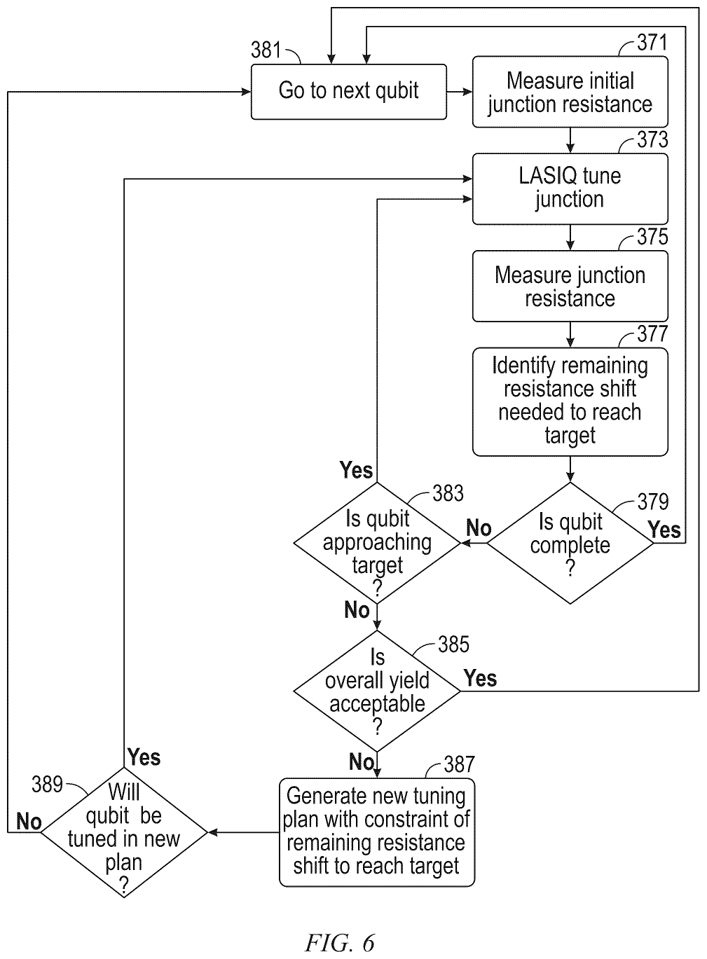

Turning now to FIG. 6, consider a scheme of tuning each qubit to a tuning plan with an integrated in-situ yield check and tuning plan generator. One or more embodiments tune positively in resistance or negatively in frequency. In the example of FIG. 6, tune one qubit at a time, and if the qubit being tuned cannot reach target frequency, then regenerate the tuning plan based on the constraint of the particular qubit. That is to say, if the qubit undershot and cannot tune any more, the new plan will constrain that qubit and not request more tuning, and the technique moves on to another qubit. If the qubit overshot and still has tuning range (as determined from its historical tuning data), allow it to be tuned to a new target that is farther than its original target. This exemplary embodiment allows for only positive resistance tuning; other embodiments can differ. In particular, in step 371, measure initial junction resistance. In step 373, carry out LASIQ tuning. In step 375, measure junction resistance after the LASIQ tuning. In step 377, identify the remaining resistance shift required to reach the target. In decision block 379, determine whether the qubit is complete. If so (YES branch), proceed to step 381 and go to the next qubit. If the qubit is not complete (NO branch), proceed to decision block 383 and determine whether the qubit is approaching the target. If the qubit is approaching the target (YES branch of decision block 383), logical flow goes back to step 373 where LASIQ tuning continues on the same qubit. If the qubit is not approaching the target (NO branch of decision block 383), proceed to decision block 385 and determine whether the overall yield is acceptable. If so (YES branch of decision block 385), stop tuning the current qubit and proceed to step 381 and go to the next qubit. If not (NO branch of decision block 385), proceed to step 387 and generate a new tuning plan with the constraint of the remaining resistance shift available to the qubit(s), and then proceed to decision block 389. In decision block 389, determine whether the current qubit will be tuned under the new plan. If so (YES branch of decision block 389), logical flow goes back to step 373 where LASIQ tuning continues. If not (NO branch of decision block 389), proceed to step 381 and go to the next qubit.

In this exemplary embodiment, each qubit is tuned until it reaches some satisfactory completion. In other embodiments, the qubits may be tuned successively, rather than tuning an entire qubit to completion before moving to the next qubit. This latter embodiment has the benefit of allowing the individual qubits to undergo aging, whereby the resulting junction resistances are allowed to ‘relax’ closer to their final settled resistance values. Finally, note that there is a possibility that a junction or set of junctions have overshot or undershot to such an extent that no new satisfactory tuning plan may be regenerated (block 387). In such a case, the chip will be discarded (as no possibility of success remains), and a new chip will be selected and the process will start again at block 371.

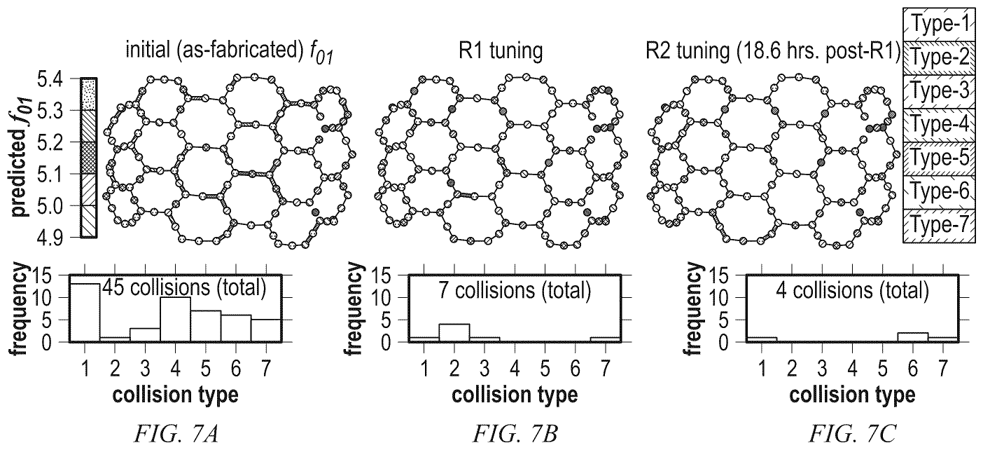

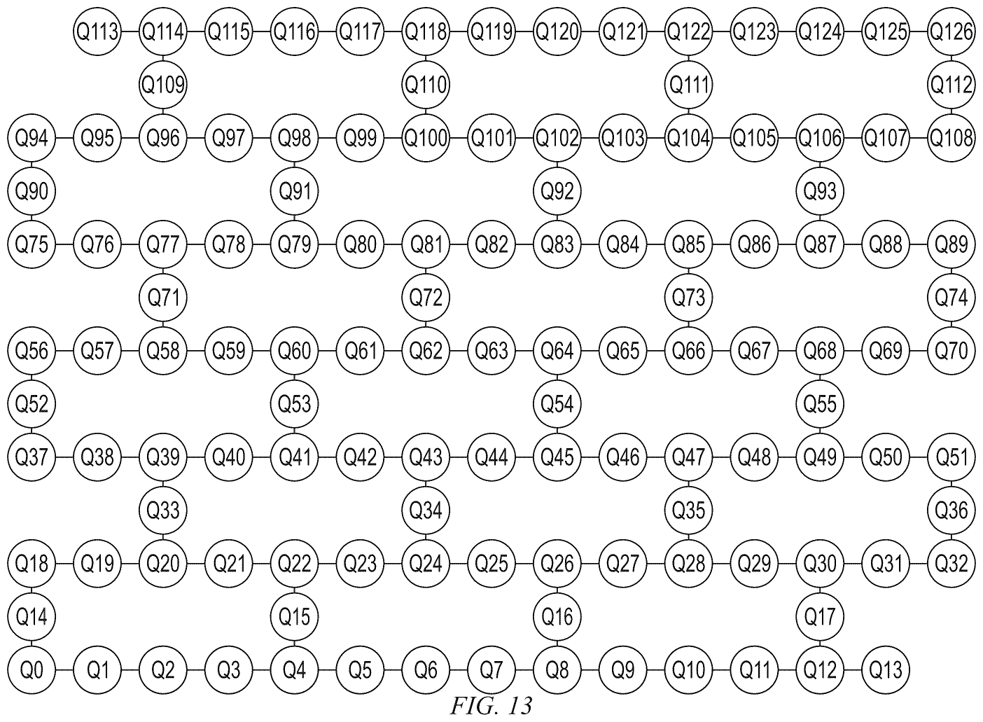

FIGS. 7A, 7B, and 7C depict examples of a single 127-qubit ‘heavy hexagon’ lattice undergoing two tuning passes, with two separate tuning plans for an exemplary chip. Note that the non-regular lattice spacing in FIGS. 7A-7C is unrelated to the tuning behavior, but results from the aspect ratio of the rendering. FIG. 13 shows a regularly-spaced rendering of such a lattice. FIG. 7A shows the initial (as-fabricated) predicted qubit frequencies, with node frequencies indicated by the legend at far left. The edges between nodes are coded according to the collision type (legend on far right). As an aside, regarding topology, various topologies can be used such as heavy-hexagonal lattice, square lattice, and the like. In general, lower average degree connectivity lattices have reduced risk of frequency collisions (due to their lower connectivity), but at the expense of an overhead for quantum computation (e.g., in the case of implementing error correcting codes). The exact topology may be selected based on the application needs of the system. The bar graphs in each of FIG. 7A, 7B, and 7C indicate the frequency of collision types. In the case of the untuned chip in FIG. 7A, forty-five total collisions are observed (using 1% gate-error bounds) and are typical of samples of this size. FIG. 7B indicates the collision count after the first tuning round (R1), with seven collisions immediate post-tuning. In this exemplary embodiment, a delay is imposed between the first and second rounds of tuning plan generation, which allows time for the qubit junctions to settle and stabilize to their final values. After about nineteen hours of aging, another round of tuning R2 is performed to mitigate the existing collisions, using a new tuning plan which accounts for distance each qubit has already been tuned. The second tuning round yields four collisions post-tuning, as seen in FIG. 7C. Note that although two rounds of tuning plan generation are depicted here, subsequent corrections may be performed to eliminate the remaining collisions from the lattice.

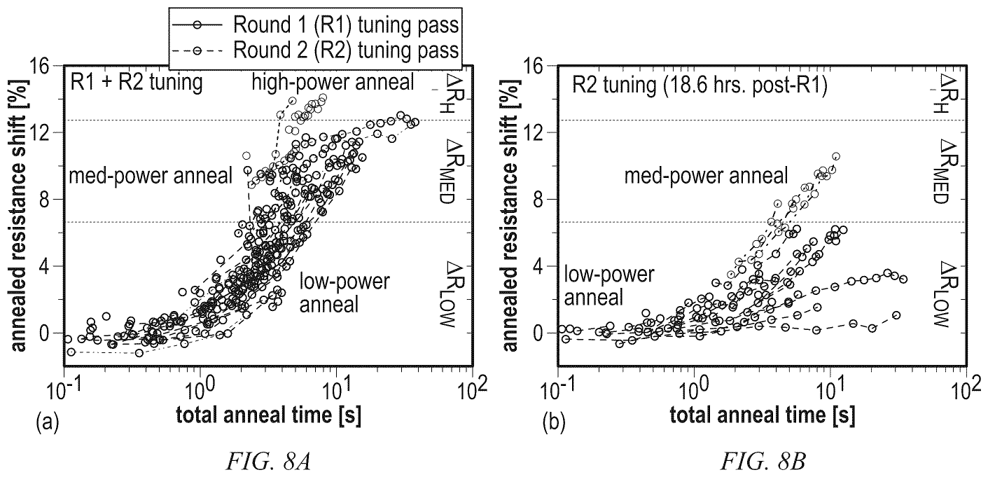

FIGS. 8A and 8B show multi-round tuning of the exemplary chip discussed with respect to FIGS. 7A-7C. FIG. 8A shows normalized resistance tuning curves over two tuning rounds (R1 and R2 are indicated by the legend in FIG. 8A), as constructed by the database containing the historical anneal progression for each qubit. During R1, the junctions were tuned to resistance targets but a number of junctions overshot their resistance targets when using the initial calibration tuning rate estimates. The tuning plan was adaptively updated to mitigate the remaining collisions post-R1 tuning, and R2 (18.6 hours later) was performed in accordance with the revised tuning plans. The low, medium, and high power anneals were selected based on the required tuning resistance-shift in R1, and as part of the calibration process whereby a plurality of junctions were tuned using different combinations of anneal power and time. The revised tuning plan was designed to ensure that no junctions surpassed 15% total tuning resistance shift. FIG. 8B shows R2 tuning curves only, indicating no detrimental tuning behavior when multiple rounds of tuning are implemented subsequent to the first tuning round. The anneal powers were selected based on the residual tuning resistance shift, and all junctions were well behaved and approached targets monotonically without adverse, or non-nominal behavior (e.g., reverse progressions, plateaus, or the like), provided they reside below the maximum tuning range as identified in the calibration process.

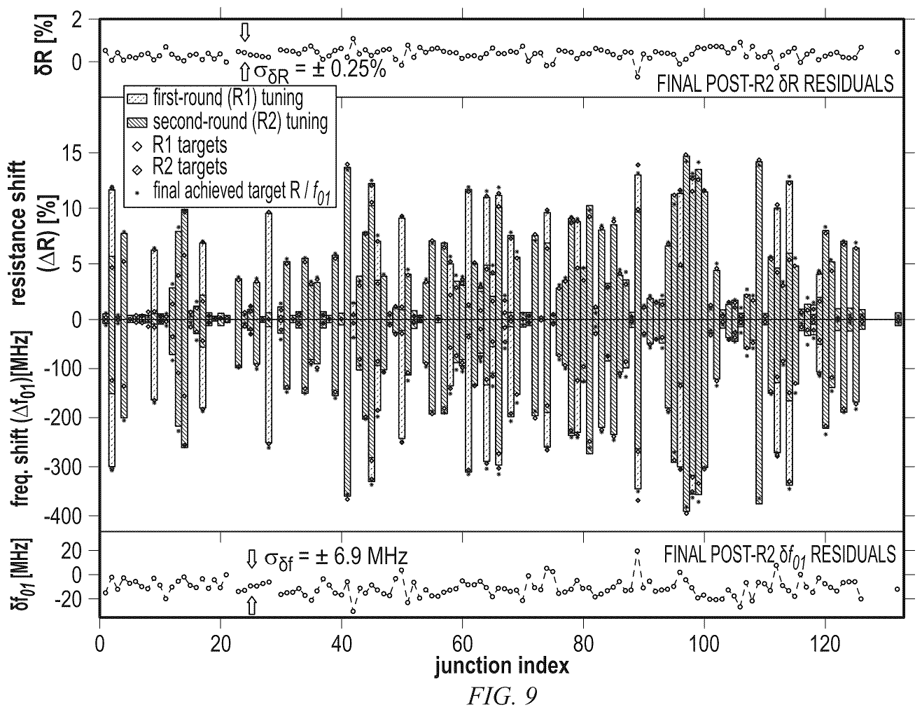

FIG. 9 shows, for the exemplary chip discussed with respect to FIGS. 7A-7C, resistance (top) and frequency (bottom) shifts after two rounds of LASIQ-v2 tuning. The first round (refer to the legend) bars resulted in over/under-shoot of numerous qubits due to poor initial calibration parameters. Post-R1 tuning, the tuning plan was adaptively redesigned to remove residual collisions, resulting in the R2 targets (refer to the legend). The corresponding frequency shifts are shown in the bottom (reversed) bar chart. The top and bottom panels show the residuals, based on a final resistance measurement after R2 tuning (i.e., short-term aging), with respect to target values. The fractional resistance precision is 0.25%, corresponding to an overall frequency precision of 6.9 MHz (bottom panel). Prior to LASIQ tuning, Q22 was open-junction and Q29 was anomalously high (˜4.2 GHz) and those qubits were accordingly disconnected from the lattice tuning plan in the design of the collision-free for patterns.

Qubits Q22 and Q29 are specific qubits shown in FIG. 13. They are missing from the lower panel of FIG. 9 due to being disconnected as just described. In FIGS. 9, Δ and δ refer to change; f refers to frequency; R refers to resistance; and o refers to an imprecision expressed in terms of a standard deviation. Where the bars corresponding to first-round tuning exceed the R1 targets, there has been an overshoot. When regenerating in the second round, the R2 targets are placed on top indicating not to do anything to the overshot qubits during the second round; tuning can be undertaken on the other (non-overshot) qubits, for example, in accordance with a new plan.

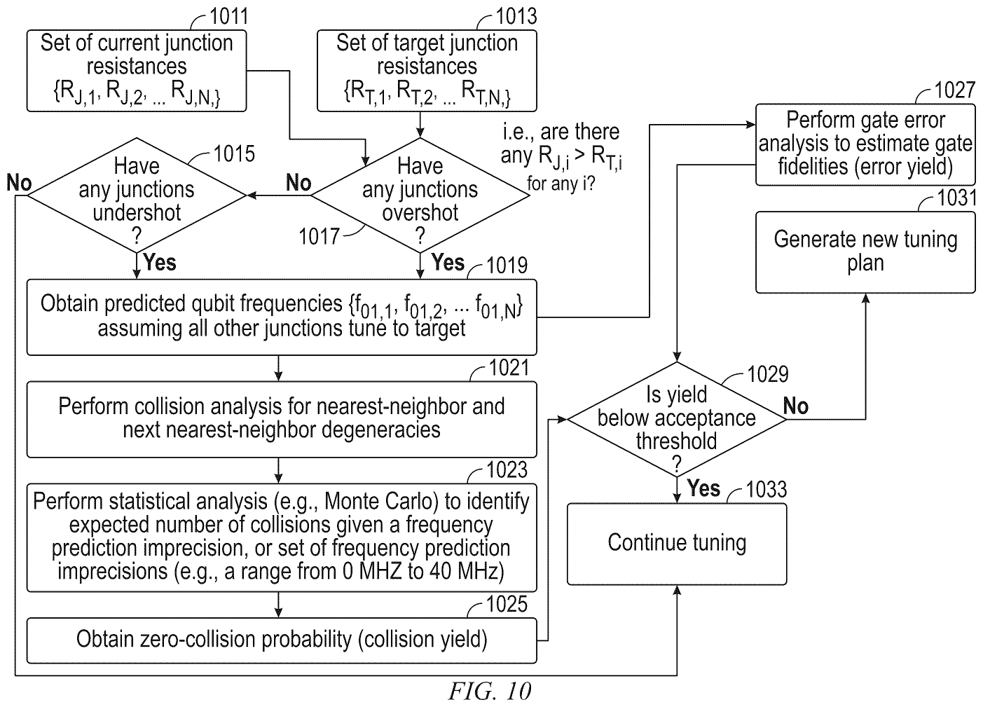

FIG. 10 depicts an exemplary detailed method by which yield can be assessed. Begin with input data 1011 (existing junction resistances as most recently measured) and 1013 (target junction resistances). Generally, yield can be divided into tuning yield and functional yield, which may involve gate error yield 1027, expected number of collisions 1023, zero-collision yield 1025, and the like. Other types of yield can also be considered, e.g., longest high gate fidelity chain that can be constructed. In decision blocks 1015 and 1017, check for undershoot and overshoot. If both decision blocks yield “NO,” proceed to 1033 and continue tuning (using either round robin or alternative as discussed elsewhere herein). If either of the decision blocks yields a “YES,” proceed to step 1019 (tuning failure), where the current junction resistances can be used to predict the current junction frequencies. Suppose two junctions fail (overshot or undershot)-their frequencies can be predicted. Suppose also that the rest of the junctions have tuned successfully. The impact of the two failed junctions on the number of collisions can be determined in step 1021. In step 1023, use Monte Carlo or other statistical analysis to determine the expected number of collisions (there is typically always some frequency spread/scramble around the prediction of every frequency (e.g., 20 MHz, 40 MHZ, 60 MHZ, . . . )). In step 1025, check the probability of success for zero collisions (or use some other outcome yield metric such as the longest attainable chain with high gate fidelity/low gate error). In decision block 1029, check for compliance of the metric(s) of interest with an acceptance threshold (can be determined heuristically by the skilled artisan for the case of interest, given the teachings herein), and continue tuning at 1033 if acceptable; else generate a new plan at 1031. Step 1027 alternatively involves gate error analysis to estimate gate fidelities (error yield), from which other metrics may also be extracted, such as longest attainable chain length having low error.

In the context of FIG. 10, yield can be understood to include at least two principal elements. The first is tuning yield, which is a measure of the precision and/or accuracy of laser tuning of the Josephson junctions. The second is functional yield, which is a measure of the number of collisions of the tuned multi-qubit lattice, zero-collision probability, gate error yield (i.e., average gate error and gate fidelity), and the like. In general, the process of screening (as in FIG. 1), which involves generating a tuning plan and assessing the quality of the tuning plan, relies on the assumption of perfect tuning yield. That is, all qubits successfully attain their targets after laser annealing. However, imperfect tuning yield will impact functional yield in the sense that qubits are no longer able to attain their target frequencies in all cases, which may impact the assessment of collisions, zero-collision probability, gate errors and the like. The embodiments described herein of real-time yield assessment and subsequent adaptive alteration to the tuning plans as shown in FIG. 6 (and FIGS. 2 and 3) therefore allows adaptation to imperfect tuning such that functional yield may be maintained even in the presence of imperfect tuning yield, thus significantly increasing the fraction of usable quantum processors that have been tuned. Equivalently, given a set number of usable processors that are desired, a smaller total set of processors need to be tuned (due to a smaller portion subsequently discarded after LASIQ due to irrecoverable functional yield), thus significantly improving overall throughput of the LASIQ process.

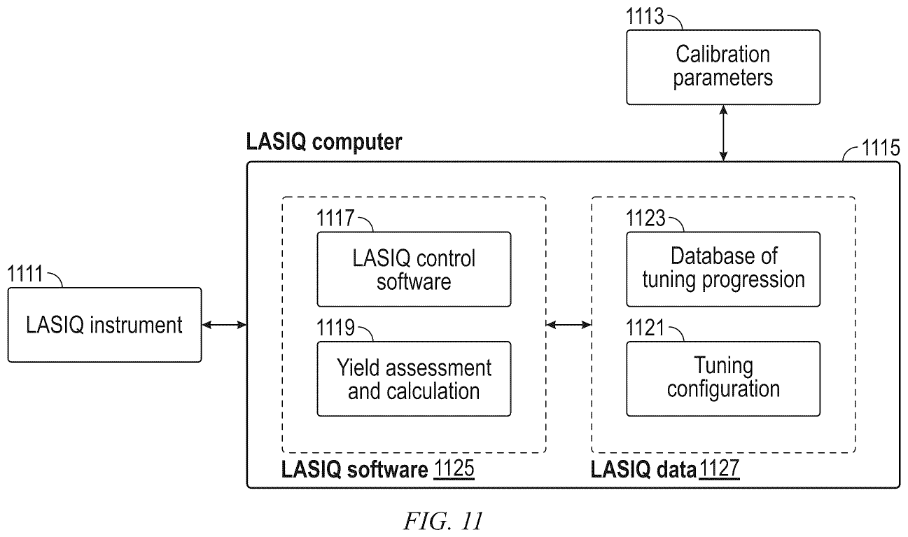

FIG. 11 provides detail of the LASIQ computer where the database 351 of FIG. 3 is stored. Note the LASIQ instrument 1111 controlled by LASIQ computer 1115, which includes LASIQ software 1125 and LASIQ data 1127. Software 1125 includes software 1117 for controlling and automating the LASIQ instrument. Software 1119 includes, e.g., gate error models, Monte Carlo models, statistical yield models, and the like, to assess chip quality. Data comes out of the instrument 1111, including, e.g., resistance measurements, which is stored on the LASIQ computer 1115. Note also the calibration parameters 1113, which arise from the calibration process whereby trial junctions are tuned. Recall that when a calibration is done on a set of trial junctions, the tuning rate and tuning range are obtained. Once calibration parameters enter the LASIQ computer, they are used in the tuning configuration 1121 of the chip being tuned. Software 1125 communicates with data 1127. Data 1127 includes database 1123 recording how each individual qubit has historically tuned, which can be reconstructed similar to FIG. 5B, and which can be used for imposing new constraints on a new plan to be generated because of tuning failures. Data 1127 also includes configuration file 1121 with information on available anneal power, available anneal time, how often to reset, and so on.

It will accordingly be appreciated that one or more embodiments tune qubit junctions to a target plan based on constraints imposed by a tuning range, as explained with regard to FIG. 1. In some instances, identify a tuning range based on calibration curves, as discussed with regard to FIGS. 4 and 5.

In some instances, when the qubit junctions do not reach their target resistances, regenerate a tuning plan (e.g., step 387) in situ with constraints based on historical qubit tuning. In one or more instances, historical qubit junction tuning includes the difference of resistance from target resistance, and the difference from maximum tunable limits. Some instances define new tuning plan constraints based on this maximum tunable limit. Some instances include a full reconstruction of qubit tuning history using a database of tuning progression (e.g. step 351) to allow new tuning frequency constraints to be determined. In one more instances, continue tuning the qubit chip to this new target plan with new constraints (e.g., step 327) as discussed above, and using historical qubit tuning progression rates to gradually approach targets.

In some embodiments, perform in situ yield monitoring (e.g., step 347) to make sure the chip candidate being tuned is still acceptable during each round of tuning. In some instances, if the predicted yield is not acceptable, generate a new tuning plan (e.g., step 387) based on new constraints. That is to say, the exemplary process is essentially like tuning a new chip instead of the original chip, subject to different constraints.

It is worth noting that one or more embodiments advantageously deal with adaptive tuning plans given new constraints of poor tuning (e.g., overshoot/undershoot in FIG. 10). Further, one or more embodiments regenerate a plan using new constraints and the existing topology of the device. Even further, one or more embodiments regenerate plans based on tuning progression and adapting to tuning imperfections and/or include real-time feedback on statistical yield analysis of tuning plans.

It will accordingly be appreciated that one or more embodiments advantageously improve tuning precision.

In one or more embodiments, all structures are made of superconducting materials on a dielectric substrate and all structures contain Josephson junctions whose tunnel-barrier is susceptible to tuning by laser-annealing. Structures may include qubits of various kinds, or SQUIDs (superconducting quantum interference devices), or single Josephson junctions, or other combinations of Josephson junctions, capacitors and inductors. They may be galvanically, inductively, or capacitively linked with neighboring structures on-chip. A qubit chip may additionally incorporate functional structures which are not qubits but which contain Josephson junctions that may be of different design and construction as compared to the qubits. A modular quantum processor design may further incorporate quantum coupling structures whose Josephson junctions are of different design or construction as compared to the Josephson junctions in the qubits and other functional structures. The several types of Josephson junctions typically undergo calibration to determine their response to laser-power and exposure time. These separate calibrations determine the tuning range specific to each type of qubit or other structure.

### Recapitulation

Given the discussion thus far, it will be appreciated that, in general terms, an exemplary method, according to an aspect of the invention, includes the step 313 of generating an initial tuning plan for a quantum computing device based on an initial screening 311. Also included are, at 317, determining whether yield rate according to the initial tuning plan is acceptable, based on real-time analytics per step 315; at steps 319 and 321, carrying out tuning based on the initial tuning plan based on the determining indicating that the yield rate according to the tuning plan is acceptable; and repeating the determining and carrying out tuning steps based on the tuning being incomplete and the yield rate according to the initial tuning plan being acceptable (e.g., while/responsive to decision block 317 yields a “YES” and decision block 323 yields a “NO”).

Some embodiments further include, responsive to a subsequent determination that the yield rate according to the tuning plan is no longer acceptable, generating a new tuning plan, and repeating, for the new tuning plan, the determining and carrying out tuning steps based on tuning being incomplete and the yield rate according to the new tuning plan being acceptable (e.g., while/responsive to decision block 317 yields a “NO” for the old plan and a “YES” for the new plan and decision block 323 yields a “NO”).

In some instances, prior to generating the new tuning plan, determine that alternate frequency constraints are possible (decision block 329: YES); and, responsive to determining that the alternate frequency constraints are possible, select new frequency constraints at 327. The new tuning plan is thus generated in response to the new frequency constraints.

It is worth noting that after a device is deployed, it is possible to apply microwave signals to shift the frequency. Generally, the same device can be tuned with two or more different frequency tuning methods; such as, for example, LASIQ and then microwave. In such a case, a new tuning plan may also be generated to apply small perturbative shifts in the qubit frequencies, as desired, to mitigate residual frequency collisions in the quantum processor.

One or more embodiments further include, responsive to a subsequent determination that tuning is complete (e.g., YES branch of block 323), carrying out post-tuning analytics at 325.

In one or more embodiments, in the step of carrying out tuning, the tuning includes LASIQ (Laser Annealing of Stochastically Impaired Qubits) tuning; however, LASIQ is a non-limiting example, and other embodiments can use other techniques, or multiple techniques for frequency tuning qubits, or quantum elements comprising Josephson junctions.

One or more embodiments further include, responsive to a subsequent determination that the yield rate according to the tuning plan is no longer acceptable (e.g., NO branch of block 317), determining that alternate frequency constraints are not possible (e.g., NO branch of block 329), terminating current tuning, and selecting one or more new chips, as at 331. It is to be noted that the term ‘current tuning’ as used herein is meant to denote a tuning iteration or tuning round in the sense of occurring in or existing at a present time, or a most recently occurring tuning iteration or tuning round, as opposed to necessarily pertaining to electrical current.

In one or more embodiments, responsive to a subsequent determination that the yield rate according to the tuning plan is no longer acceptable: estimate a remaining tuning resistance shift based on a database of tuning progression; generate a new tuning plan, based on the estimated remaining tuning resistance shift at 353; and repeat, for the new tuning plan, the determining and carrying out tuning steps based on tuning being incomplete and the yield rate according to the new tuning plan being acceptable. See, e.g., FIG. 3, decision block 349 NO, step 353, and steps 343/341.

In one or more embodiments, when repeating the steps of determining and carrying out tuning, for each repetition, all junctions of a chip are tuned and aging is carried out between repetitions.

For example, in some embodiments, block 373 in FIG. 6 tunes on a single junction and keeps iterating on the same junction over and over again. However, it is also possible to loop through all junctions of a chip in a round-robin format; there is then a relaxation and/or settling time of junction resistance after tuning, and after the relaxation and/or settling, the method comes back and loops through all the junctions again in a subsequent round-robin.

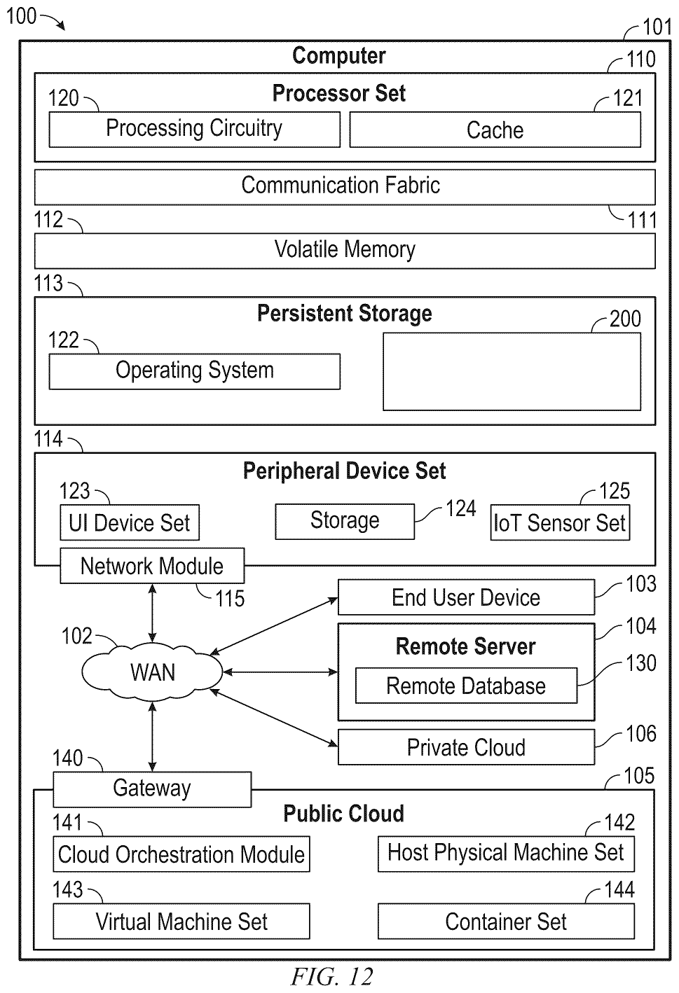

In another aspect (refer, e.g., to discussion of FIG. 12), a computer program product includes a computer readable storage medium having program instructions embodied therewith. The program instructions are executable by a processor such as 110 to cause the processor to perform any one, some, or all of the method steps herein; for example, method steps of generating an initial tuning plan for a quantum computing device based on an initial screening; determining whether yield rate according to the initial tuning plan is acceptable, based on real-time analytics; facilitating carrying out tuning based on the initial tuning plan based on the determining indicating that the yield rate according to the tuning plan is acceptable; and repeating the determining and facilitating carrying out tuning steps based on tuning being incomplete and the yield rate according to the initial tuning plan being acceptable.

Optionally, the method performed by the processor further includes, responsive to a subsequent determination that the yield rate according to the tuning plan is no longer acceptable, generating a new tuning plan, and repeating, for the new tuning plan, the determining and facilitating carrying out tuning steps based on tuning being incomplete and the yield rate according to the new tuning plan being acceptable.

Optionally, the method performed by the processor further includes, prior to generating the new tuning plan, determining that alternate frequency constraints are possible; and responsive to determining that the alternate frequency constraints are possible, selecting new frequency constraints. The new tuning plan is generated in response to the new frequency constraints.

Optionally, the method performed by the processor further includes, responsive to a subsequent determination that tuning is complete, carrying out post-tuning analytics.

Generally, method steps disclosed herein can be performed by software on LASIQ computer 1115 and/or a remote computer interacting with same to control LASIQ instrument 1111. Techniques can be implemented by the algorithms disclosed herein or, where specific algorithms are not disclosed, by adapting known techniques as will be apparent to the skilled artisan.

In another aspect, an exemplary system (which could be implemented, for example, as per FIG. 12; see also FIG. 11 wherein the LASIQ computer controls instrument 1111) includes a memory such as 113; and at least one processor such as 110, coupled to the memory, and operative to perform any one, some, or all of the method steps herein; for example, operative to generate an initial tuning plan for a quantum computing device based on an initial screening; determine whether yield rate according to the initial tuning plan is acceptable, based on real-time analytics; facilitate carrying out tuning based on the initial tuning plan based on the determining indicating that the yield rate according to the tuning plan is acceptable; and repeat the determining and facilitating carrying out tuning steps based on tuning being incomplete and the yield rate according to the initial tuning plan being acceptable.

In one or more embodiments, the at least one processor is further operative to, responsive to a subsequent determination that the yield rate according to the tuning plan is no longer acceptable, generate a new tuning plan, and repeat, for the new tuning plan, the determining and facilitating carrying out tuning steps based on tuning being incomplete and the yield rate according to the new tuning plan being acceptable.

In one or more embodiments, the at least one processor is further operative to, prior to generating the new tuning plan, determine that alternate frequency constraints are possible; and responsive to determining that the alternate frequency constraints are possible, select new frequency constraints; the new tuning plan is generated in response to the new frequency constraints.

In one or more embodiments, the at least one processor is further operative to, responsive to a subsequent determination that tuning is complete, carry out post-tuning analytics.

In one or more embodiments, the tuning includes LASIQ (Laser Annealing of Stochastically Impaired Qubits) tuning.

In one or more embodiments, the at least one processor is further operative to, responsive to a subsequent determination that the yield rate according to the tuning plan is no longer acceptable, determine that alternate frequency constraints are not possible, terminate current tuning, and select one or more new chips.

In one or more embodiments, the at least one processor is further operative to, responsive to a subsequent determination that the yield rate according to the tuning plan is no longer acceptable: estimate a remaining tuning resistance shift based on a database of tuning progression; generate a new tuning plan, based on the estimated remaining tuning resistance shift; and repeat, for the new tuning plan, the determining and carrying out tuning steps based on tuning being incomplete and the yield rate according to the new tuning plan being acceptable.

In some cases, when repeating the steps of determining and carrying out tuning, for each repetition, all junctions of a chip are tuned and aging is carried out between repetitions. Generally, by way of example, when repeating the steps of determining and carrying out tuning, for each repetition, all junctions of a chip can be tuned and relaxation and/or settling of junction resistances, or aging can be carried out between repetitions.

The skilled artisan will appreciate that LASIQ tuning is a physical process, wherein a computer-controlled machine 1111 is making physical changes to the Josephson junction. When complete, the end result is a quantum computing device configured and tuned in accordance with techniques disclosed herein, which can be deployed and can carry out quantum calculations. The way in which yield is characterized advantageously ties into usability-good yield metrics are a direct measure of the usability of the quantum processor for quantum computations. Also, regarding the Gamma calculator-Gamma is an expression of overhead for how many computer runs must be made/time of compute.

Refer now to FIG. 12, it being understood that techniques disclosed herein include, for example, computer-aided design of a quantum computer, wherein the aspects of the design process can be implemented on any kind of computer, quantum or conventional.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

Refer now to FIG. 12.

Computing environment 100 contains an example of an environment for the execution of at least some of the computer code involved in performing the inventive methods, as seen at 200 (e.g., code for adaptive mitigation of frequency crowding of superconducting qubits via laser annealing). In addition to block 200, computing environment 100 includes, for example, computer 101, wide area network (WAN) 102, end user device (EUD) 103, remote server 104, public cloud 105, and private cloud 106. In this embodiment, computer 101 includes processor set 110 (including processing circuitry 120 and cache 121), communication fabric 111, volatile memory 112, persistent storage 113 (including operating system 122 and block 200, as identified above), peripheral device set 114 (including user interface (UI) device set 123, storage 124, and Internet of Things (IoT) sensor set 125), and network module 115. Remote server 104 includes remote database 130. Public cloud 105 includes gateway 140, cloud orchestration module 141, host physical machine set 142, virtual machine set 143, and container set 144.

COMPUTER 101 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 130. As is well understood in the art of computer technology, and depending upon the technology, performance of a computer-implemented method may be distributed among multiple computers and/or between multiple locations. On the other hand, in this presentation of computing environment 100, detailed discussion is focused on a single computer, specifically computer 101, to keep the presentation as simple as possible. Computer 101 may be located in a cloud, even though it is not shown in a cloud in FIG. 13. On the other hand, computer 101 is not required to be in a cloud except to any extent as may be affirmatively indicated.

PROCESSOR SET 110 includes one, or more, computer processors of any type now known or to be developed in the future. Processing circuitry 120 may be distributed over multiple packages, for example, multiple, coordinated integrated circuit chips. Processing circuitry 120 may implement multiple processor threads and/or multiple processor cores. Cache 121 is memory that is located in the processor chip package(s) and is typically used for data or code that should be available for rapid access by the threads or cores running on processor set 110. Cache memories are typically organized into multiple levels depending upon relative proximity to the processing circuitry. Alternatively, some, or all, of the cache for the processor set may be located “off chip.” In some computing environments, processor set 110 may be designed for working with qubits and performing quantum computing.

Computer readable program instructions are typically loaded onto computer 101 to cause a series of operational steps to be performed by processor set 110 of computer 101 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 121 and the other storage media discussed below. The program instructions, and associated data, are accessed by processor set 110 to control and direct performance of the inventive methods. In computing environment 100, at least some of the instructions for performing the inventive methods may be stored in block 200 in persistent storage 113.

Computer readable program instructions are typically loaded onto computer 101 to cause a series of operational steps to be performed by processor set 110 of computer 101 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 121 and the other storage media discussed below. The program instructions, and associated data, are accessed by processor set 110 to control and direct performance of the inventive methods. In computing environment 100, at least some of the instructions for performing the inventive methods may be stored in block 200 in persistent storage 113.

COMMUNICATION FABRIC 111 is the signal conduction path that allows the various components of computer 101 to communicate with each other. Typically, this fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

VOLATILE MEMORY 112 is any type of volatile memory now known or to be developed in the future. Examples include dynamic type random access memory (RAM) or static type RAM. Typically, volatile memory 112 is characterized by random access, but this is not required unless affirmatively indicated. In computer 101, the volatile memory 112 is located in a single package and is internal to computer 101, but, alternatively or additionally, the volatile memory may be distributed over multiple packages and/or located externally with respect to computer 101.

PERSISTENT STORAGE 113 is any form of non-volatile storage for computers that is now known or to be developed in the future. The non-volatility of this storage means that the stored data is maintained regardless of whether power is being supplied to computer 101 and/or directly to persistent storage 113. Persistent storage 113 may be a read only memory (ROM), but typically at least a portion of the persistent storage allows writing of data, deletion of data and re-writing of data. Some familiar forms of persistent storage include magnetic disks and solid state storage devices. Operating system 122 may take several forms, such as various known proprietary operating systems or open source Portable Operating System Interface-type operating systems that employ a kernel. The code included in block 200 typically includes at least some of the computer code involved in performing the inventive methods.

PERIPHERAL DEVICE SET 114 includes the set of peripheral devices of computer 101. Data communication connections between the peripheral devices and the other components of computer 101 may be implemented in various ways, such as Bluetooth connections, Near-Field Communication (NFC) connections, connections made by cables (such as universal serial bus (USB) type cables), insertion-type connections (for example, secure digital (SD) card), connections made through local area communication networks and even connections made through wide area networks such as the internet. In various embodiments, UI device set 123 may include components such as a display screen, speaker, microphone, wearable devices (such as goggles and smart watches), keyboard, mouse, printer, touchpad, game controllers, and haptic devices. Storage 124 is external storage, such as an external hard drive, or insertable storage, such as an SD card. Storage 124 may be persistent and/or volatile. In some embodiments, storage 124 may take the form of a quantum computing storage device for storing data in the form of qubits. In embodiments where computer 101 is required to have a large amount of storage (for example, where computer 101 locally stores and manages a large database) then this storage may be provided by peripheral storage devices designed for storing very large amounts of data, such as a storage area network (SAN) that is shared by multiple, geographically distributed computers. IoT sensor set 125 is made up of sensors that can be used in Internet of Things applications. For example, one sensor may be a thermometer and another sensor may be a motion detector.

NETWORK MODULE 115 is the collection of computer software, hardware, and firmware that allows computer 101 to communicate with other computers through WAN 102. Network module 115 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 115 are performed on the same physical hardware device. In other embodiments (for example, embodiments that utilize software-defined networking (SDN)), the control functions and the forwarding functions of network module 115 are performed on physically separate devices, such that the control functions manage several different network hardware devices. Computer readable program instructions for performing the inventive methods can typically be downloaded to computer 101 from an external computer or external storage device through a network adapter card or network interface included in network module 115.

WAN 102 is any wide area network (for example, the internet) capable of communicating computer data over non-local distances by any technology for communicating computer data, now known or to be developed in the future. In some embodiments, the WAN 102 may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

END USER DEVICE (EUD) 103 is any computer system that is used and controlled by an end user (for example, a customer of an enterprise that operates computer 101), and may take any of the forms discussed above in connection with computer 101. EUD 103 typically receives helpful and useful data from the operations of computer 101. For example, in a hypothetical case where computer 101 is designed to provide a recommendation to an end user, this recommendation would typically be communicated from network module 115 of computer 101 through WAN 102 to EUD 103. In this way, EUD 103 can display, or otherwise present, the recommendation to an end user. In some embodiments, EUD 103 may be a client device, such as thin client, heavy client, mainframe computer, desktop computer and so on.

REMOTE SERVER 104 is any computer system that serves at least some data and/or functionality to computer 101. Remote server 104 may be controlled and used by the same entity that operates computer 101. Remote server 104 represents the machine(s) that collect and store helpful and useful data for use by other computers, such as computer 101. For example, in a hypothetical case where computer 101 is designed and programmed to provide a recommendation based on historical data, then this historical data may be provided to computer 101 from remote database 130 of remote server 104.

PUBLIC CLOUD 105 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 105 is performed by the computer hardware and/or software of cloud orchestration module 141. The computing resources provided by public cloud 105 are typically implemented by virtual computing environments that run on various computers making up the computers of host physical machine set 142, which is the universe of physical computers in and/or available to public cloud 105. The virtual computing environments (VCEs) typically take the form of virtual machines from virtual machine set 143 and/or containers from container set 144. It is understood that these VCEs may be stored as images and may be transferred among and between the various physical machine hosts, either as images or after instantiation of the VCE. Cloud orchestration module 141 manages the transfer and storage of images, deploys new instantiations of VCEs and manages active instantiations of VCE deployments. Gateway 140 is the collection of computer software, hardware, and firmware that allows public cloud 105 to communicate through WAN 102.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

PRIVATE CLOUD 106 is similar to public cloud 105, except that the computing resources are only available for use by a single enterprise. While private cloud 106 is depicted as being in communication with WAN 102, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 105 and private cloud 106 are both part of a larger hybrid cloud.

One or more embodiments of the invention, or elements thereof, can thus be implemented in the form of an apparatus including a memory and at least one processor that is coupled to the memory and operative to perform exemplary method steps. FIG. 13 depicts a computer system that may be useful in implementing one or more aspects and/or elements of the invention

It should be noted that any of the methods described herein can include an additional step of providing a system comprising distinct software modules embodied on a computer readable storage medium; the modules can include, for example, any or all of the appropriate elements depicted in the block diagrams and/or described herein; by way of example and not limitation, any one, some or all of the modules/blocks and or sub-modules/sub-blocks described. The method steps can then be carried out using the distinct software modules and/or sub-modules of the system, as described above, executing on one or more hardware processors. Further, a computer program product can include a computer-readable storage medium with code adapted to be implemented to carry out one or more method steps described herein, including the provision of the system with the distinct software modules.

One example of user interface that could be employed in some cases is hypertext markup language (HTML) code served out by a server or the like, to a browser of a computing device of a user. The HTML is parsed by the browser on the user's computing device to create a graphical user interface (GUI).

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A method comprising:
generating an initial tuning plan for a quantum computing device based on an initial screening;
determining whether yield rate according to the initial tuning plan is acceptable, based on real-time analytics;
facilitating carrying out tuning based on the initial tuning plan based on the determining indicating that the yield rate according to the tuning plan is acceptable; and
repeating the determining and facilitating carrying out tuning steps based on tuning being incomplete and the yield rate according to the initial tuning plan being acceptable.

2. The method of claim 1, further comprising, responsive to a subsequent determination that the yield rate according to the tuning plan is no longer acceptable, generating a new tuning plan, and repeating, for the new tuning plan, the determining and facilitating carrying out tuning steps based on tuning being incomplete and the yield rate according to the new tuning plan being acceptable.

3. The method of claim 2, further comprising:
prior to generating the new tuning plan, determining that alternate frequency constraints are possible; and
responsive to determining that the alternate frequency constraints are possible, selecting new frequency constraints;
wherein the new tuning plan is generated in response to the new frequency constraints.

4. The method of claim 1, further comprising, responsive to a subsequent determination that tuning is complete, carrying out post-tuning analytics.

5. The method of claim 1, wherein, in the step of carrying out tuning, the tuning comprises LASIQ (Laser Annealing of Stochastically Impaired Qubits) tuning.

6. The method of claim 1, further comprising, responsive to a subsequent determination that the yield rate according to the tuning plan is no longer acceptable, determining that alternate frequency constraints are not possible, terminating current tuning, and selecting one or more new chips.

7. The method of claim 1, further comprising, responsive to a subsequent determination that the yield rate according to the tuning plan is no longer acceptable:
estimating a remaining tuning resistance shift based on a database of tuning progression;
generating a new tuning plan, based on the estimated remaining tuning resistance shift; and
repeating, for the new tuning plan, the determining and facilitating carrying out tuning steps based on tuning being incomplete and the yield rate according to the new tuning plan being acceptable.

8. The method of claim 1, wherein, when repeating the steps of determining and facilitating carrying out tuning, for each repetition, all junctions of a chip are tuned and aging is carried out between repetitions.

9. A computer program product comprising a computer readable storage medium having program instructions embodied therewith, the program instructions executable by a processor to cause the processor to perform a method comprising:
generating an initial tuning plan for a quantum computing device based on an initial screening;
determining whether yield rate according to the initial tuning plan is acceptable, based on real-time analytics;
facilitating carrying out tuning based on the initial tuning plan based on the determining indicating that the yield rate according to the tuning plan is acceptable; and
repeating the determining and facilitating carrying out tuning steps based on tuning being incomplete and the yield rate according to the initial tuning plan being acceptable.

10. The computer program product of claim 9, wherein the method performed by the processor further comprises responsive to a subsequent determination that the yield rate according to the tuning plan is no longer acceptable, generating a new tuning plan, and repeating, for the new tuning plan, the determining and facilitating carrying out tuning steps based on tuning being incomplete and the yield rate according to the new tuning plan being acceptable.

11. The computer program product of claim 10, wherein the method performed by the processor further comprises:
prior to generating the new tuning plan, determining that alternate frequency constraints are possible; and
responsive to determining that the alternate frequency constraints are possible, selecting new frequency constraints;
wherein the new tuning plan is generated in response to the new frequency constraints.

12. The computer program product of claim 9, wherein the method performed by the processor further comprises, responsive to a subsequent determination that tuning is complete, carrying out post-tuning analytics.

13. An apparatus comprising:
a memory; and
at least one processor, coupled to said memory, and operative to:
generate an initial tuning plan for a quantum computing device based on an initial screening;
determine whether yield rate according to the initial tuning plan is acceptable, based on real-time analytics;
facilitate carrying out tuning based on the initial tuning plan based on the determining indicating that the yield rate according to the tuning plan is acceptable; and
repeat the determining and facilitating carrying out tuning steps based on tuning being incomplete and the yield rate according to the initial tuning plan being acceptable.

14. The apparatus of claim 13, wherein the at least one processor is further operative to, responsive to a subsequent determination that the yield rate according to the tuning plan is no longer acceptable, generate a new tuning plan, and repeat, for the new tuning plan, the determining and facilitating carrying out tuning steps based on tuning being incomplete and the yield rate according to the new tuning plan being acceptable.

15. The apparatus of claim 14, wherein the at least one processor is further operative to:
prior to generating the new tuning plan, determine that alternate frequency constraints are possible; and
responsive to determining that the alternate frequency constraints are possible, select new frequency constraints;
wherein the new tuning plan is generated in response to the new frequency constraints.

16. The apparatus of claim 13, wherein the at least one processor is further operative to, responsive to a subsequent determination that tuning is complete, carry out post-tuning analytics.

17. The apparatus of claim 13, wherein the tuning comprises LASIQ (Laser Annealing of Stochastically Impaired Qubits) tuning.

18. The apparatus of claim 13, wherein the at least one processor is further operative to, responsive to a subsequent determination that the yield rate according to the tuning plan is no longer acceptable, determine that alternate frequency constraints are not possible, terminate current tuning, and select one or more new chips.

19. The apparatus of claim 13, wherein the at least one processor is further operative to, responsive to a subsequent determination that the yield rate according to the tuning plan is no longer acceptable:
estimate a remaining tuning resistance shift based on a database of tuning progression;
generate a new tuning plan, based on the estimated remaining tuning resistance shift; and
repeat, for the new tuning plan, the determining and carrying out tuning steps based on tuning being incomplete and the yield rate according to the new tuning plan being acceptable.

20. The apparatus of claim 13, wherein, when repeating the steps of determining and carrying out tuning, for each repetition, all junctions of a chip are tuned and aging is carried out between repetitions.
